(19) United States
(12) Patent Application Publication
(10) Pub. No.: US 2003/0222730 A1
(43) Pub. Date: Dec. 4, 2003

(54) Impedance matching circuit and noise filter equipped with the same

(75) Inventors: Ryu Watanabe, Saiatam (JP); Hideaki Tanaka, Saitama (JP); Masatoshi Suzuki, Saitama (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: KDDI Corporation, Tokyo (JP)

(21) Appl. No.: 10/437,043

(22) Filed: May 14, 2003

(30) Foreign Application Priority Data
Jun. 3, 2002 (JP) 2002-161893

(51) Int. Cl. H03H 7/38; H03H 7/01

(52) U.S. Cl. 333/32; 333/181

(57) ABSTRACT

A bridge tap branches from a two-wire transmission line for communications and is connected to a terminal-function assisted noise filter which is then connected at the downstream end with a telephone. The terminal-function assisted noise filter comprises a terminal circuit (an impedance matching circuit with four ports) and a noise removing circuit. The terminal circuit consists mainly of two resistors connected in series with the bridge tap and a capacitor connected in parallel with the same. Accordingly, the impedance matching circuit and the noise filter equipped with the impedance matching circuit can be implemented where the communicating action of a data communication device over the main line is protected from being interfered by reflection waves derived from the bridge tap.

### BACKGROUND OF THE INVENTION

1. Field of the Invention

The present invention relates to an impedance matching circuit and a noise filter equipped with the same. Particularly, it relates to an impedance matching circuit arranged favorably applicable to an terminal circuit of a system where a data signal and a telephone signal are multiplexed for transmission over a single communication line and to a noise filter equipped with the impedance matching circuit.

2. Description of the Related Art

There is known a system (namely VDSL) for data communications over a two-wire balanced telephone line with impedance matching as the transmission line using a high frequency range which is different from the frequency range of telephone service. An example of the conventional system linked to each home for allowing both of data communications of a communication device and the telephone service over a single transmission line will be explained referring to FIG. 5.

A main line 1 such as the telephone line is connected at both ends to a couple of data communication devices (modems) 2 and 3. It is assumed that one of the modems, the modem 2 in this embodiment, serves as a center modem, base modem, or master modem while the other, the modem 3, serves as a user modem, terminal modem, or slave modem. As a telephone signal from the telephone station and a communication signal from the center modem 2 are transmitted over the main line 1, a signal mixer or splitter 4 with a filter is provided across the main line 1 for reducing any noise derived from the telephone signal. Also, the main line 1 has a branch line extending from a node 5 for connecting via a filter 6 to a telephone 7. The branch line is called as a bridge tap 8 extending from the node 5 to the telephone 7.

The filter 6 is provided for protecting the modems from being interfered by a noise received on the main line 1 from the telephone 7. The filter 6 may be implemented by a set of inductors L and capacitors C as shown in FIG. 6A, 6B, or 6C.

The conventional system however fails to satisfy the terminal end of the bridge tap 8. The installation of the filter 6 may hardly protect the data communication signal from being interfered by unwanted reflection waves from the bridge tap 8.

### SUMMARY OF THE INVENTION

It is hence an object of the present invention to provide an impedance matching circuit and a noise filter equipped with the circuit capable of protecting the data communication of a data communication device from being interfered by reflection waves from a bridge tap.

In order to accomplish the object, as a first feature of the present invention, an impedance matching circuit is provided with four port circuit comprising resistors connected in series with the two-wire transmission line and a capacitor connected in parallel with the two-wire transmission line. According to the first feature, devices such as a telephone permits to be connected to the downstream end of the impedance matching circuit.

As a second feature of the present invention, a noise filter is provided comprising an impedance matching circuit and a filter circuit comprising inductors and capacitors connected to the impedance matching circuit. According to a third feature of the present invention, the capacitor in the impedance matching circuit may be eliminated when its action is conducted by the filter circuit. The. second and third features can protect the two-wire transmission line for communications from the adverse effects of noises generated by a device such as a telephone connected to the downstream end of the noise filter.

According to a fourth feature of the present invention, when a telephone is linked to a bridge tap branching from the main line of a communication device designed for performing communications over the two-wire transmission line, the noise filter may be connected to the upstream end of the telephone. This allows the noise filter to protect the data communication signals of the communication device, e.g. VDSL, from being attenuated in the amplitude or interfered by noises derived from the telephone.

### BRIEF DESCRIPTION OF THE DRAWINGS

FIG. 1 is a block diagram showing a primary part of one embodiment of the present invention;

FIG. 2 is a circuitry diagram of an exemplary arrangement of the embodiment;

FIG. 3 is a graphic diagram showing the adverse effect of a bridge tap over the main line;

FIG. 4 is a circuitry diagram of a conventional terminal resistor;

FIG. 5 is a circuitry diagram of a conventional VDSL system; and

FIGS. 6A, 6B, and 6C are circuitry diagrams showing different arrangements of a conventional balanced filter.

### DETAILED DESCRIPTION OF THE PREFERRED EMBODIMENT

The present invention will be described in more detail referring to the relevant drawings. A reason why the present invention has been developed is briefly explained.

It is known in such a VDSL system as shown in FIG. 5 that when a bridge tap 8 is not connected with a telephone but remains free, i.e. the bridge tap 8 has an open end thus failing to provide impedance matching, a signal reflected at the open end returns back to a node 5 and may interfere and suppress the main signal on the main line 1 when its phase has been inverted and opposite to that of the main signal. As the result, the main signal on the main line 1 will have a notch-like decay. The notch-like decays appear at a frequency equal to 1/4 the electrical length of the bridge tap 8 and a frequency shifted by π of the angular frequency from the 1/4 the electrical length, i.e. 3/4 or 5/4 the wavelength. FIG. 3 illustrates two different profiles (a) and (b) of the main signal without and with the bridge tap 8 (of 26 meter long) respectively. (b) shows the notch-like decays of the main signal due to undesired reflected signals from the bridge tap 8.

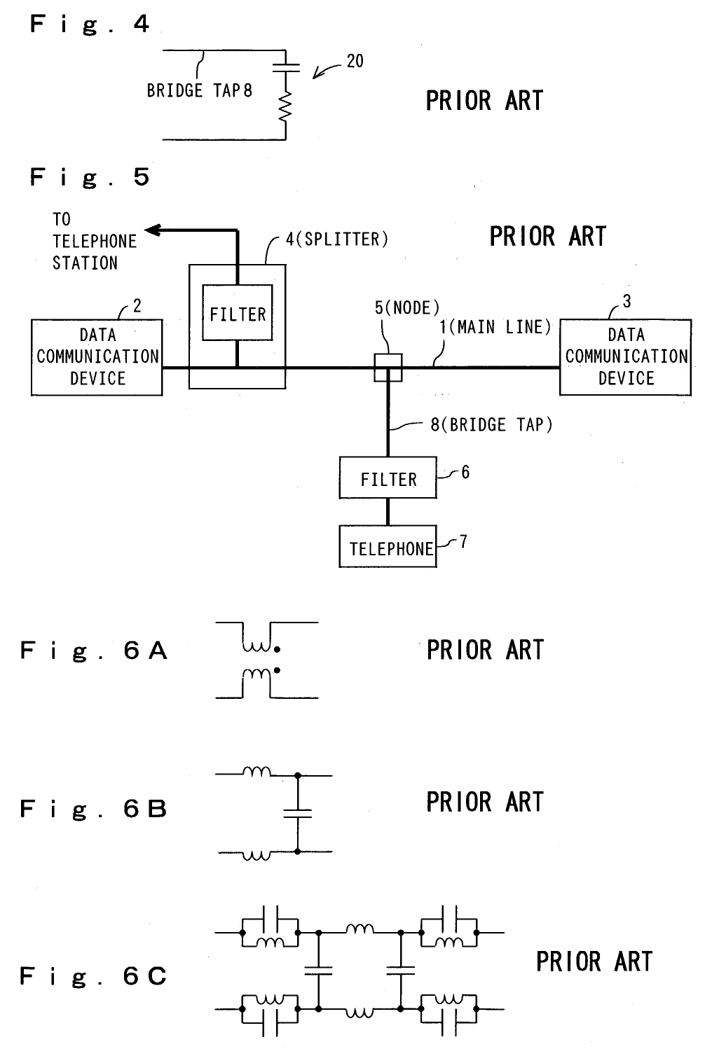

For providing the impedance matching, the open end of the bridge tap 8 may be linked with a terminal resistor 20 to compensate the decay of the signal on the main line 1 as shown in FIG. 4.

However, the terminal resistor 20 is designed simply for providing the impedance matching and can hardly permit a filter 6 or a telephone 7 to be connected to its other end.

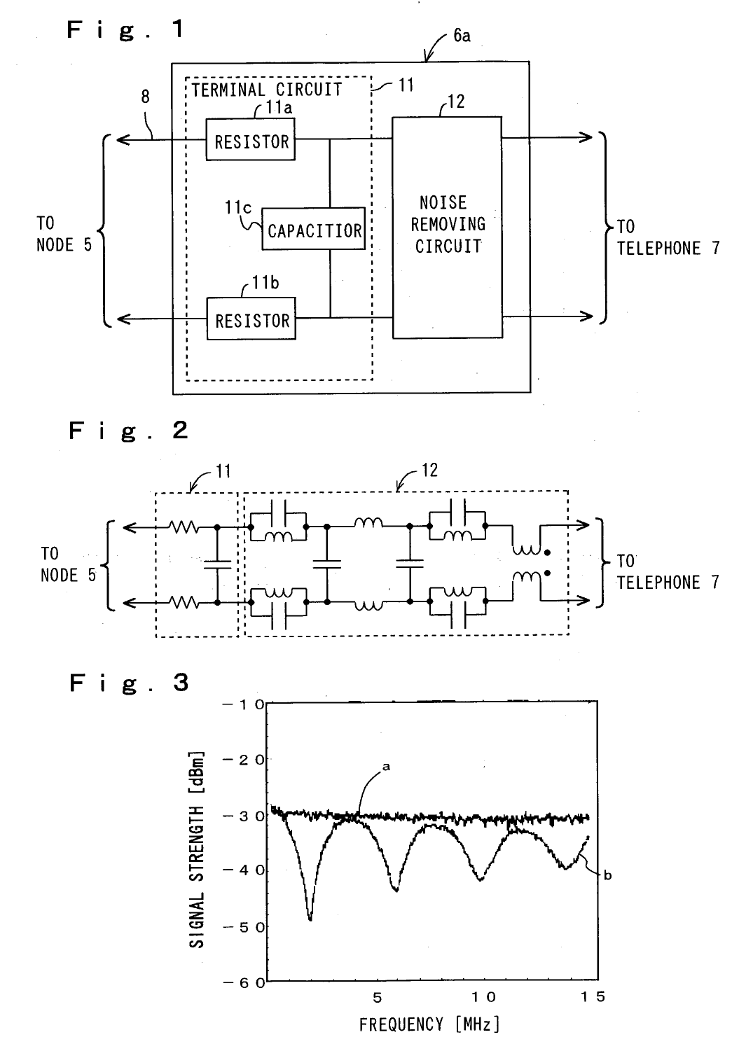

For eliminating the above drawback, the present invention has been developed and its embodiment will now be described. FIG. 1 is a block diagram showing a primary part of the embodiment of the present invention. In particular, the filter 6 shown in FIG. 5 is replaced by a terminal-function assisted noise filter 6a, i.e. noise filter equipped with the. terminal-function.

The terminal-function assisted noise filter 6a comprises a terminal circuit 11 and a noise removing circuit 12. The terminal circuit 11 incorporates an impedance matching device with four ports which consists mainly of two resistors 11a and 11b connected in series with two-wire line of the bridge tap 8 and a capacitor 11c connected in parallel with it. The noise removing circuit 12 may be implemented by any of filter arrangements shown in FIGS. 6A, 6B, and 6C.

According to the embodiment, noises generated by the telephone 7 can favorably be removed by the noise removing circuit 12 and are not received by the main line 1. Simultaneously, as the bridge tap 8 is terminated with the terminal circuit 11, an undesired reflected signal from it can significantly be suppressed thus permitting the main signal on the main line 1 to be free from decaying.

FIG. 2 is a circuitry diagram showing an example of the terminal-function assisted noise filter 6a. The terminal circuit 11 includes two resistors connected in series with the two-wire line and a capacitor connected in parallel with the two-wire line thus forming an impedance matching circuit with four ports. The noise removing circuit 12 is a filter circuit comprising inductors and capacitors. The resistors 11a and 11b and the capacitor 11c in the terminal circuit 11 are set with predetermined constants for ensuring the impedance matching. An optimum result is given when each of the resistors 11a and 11b is 50 Ω and the capacitor 11c is 3 nF, providing that the impedance of the telephone line served as a balanced line is 100 Ω. Alternatively, the resistance of the resistors 11a and 11b may be from 5 Ω to 500 Ω with equal success while the capacitor 11c ranges from 1 nF to 1 μF.

Since the VDSL system is required for removing any noise generated by a telephone, its filter circuit is preferably a lowpass filter for passing a low band of frequencies. It is most desirable in the Japanese ISDN or TCM-ISDN system that the blocking frequency of the lowpass filter is 400 kHz. Alternatively, the blocking frequency of the lowpass filter may be with equal success from 330 kHz to 900 kHz which is the lower limit of a frequency band to be used in VDSL system.

It was proved from a series of experiments that the terminal-function assisted noise filter 6a connected in such a VDSL system shown in FIG. 5 successfully minimized the generation of decays in the signal on the main line 1 which were peaked at specific frequencies determined by the length of the bridge tap 8 and thus removed noises produced by the telephone.

The noise removing circuit 12 connected to the downstream end of the terminal circuit 11 may serve as the capacitor 11c in the terminal circuit 11 when its arrangement is so designed. This allows the capacitor 11c to be eliminated while the two resistors 11a and 11b remain connected. Also, when the noise generated by the telephone 7 is small enough to need no attenuation, the noise removing circuit 12 may be eliminated. This permits the terminal circuit 11 to be connected directly to the telephone 7.

While the embodiment of the present invention is implemented with the balanced circuit arrangement, it can be applied with equal success to a non-balanced circuit system through modifying the construction of the terminal circuit 11 and the noise removing circuit 12.

As clearly apparent from the above description, the present invention can favorably provide an impedance matching circuit with four ports where a two-wire communication line such as a bridge tap is terminated and enabled to connect at its downstream end with an external device such as a telephone. Accordingly, the reflection of a signal at the bridge tap can be avoided hence minimizing its interference with the main signal which runs along the main transmission line of a system.

Also, the present invention protects the main transmission line for communications from being interrupted by any noise regardless of a noise generating device, such as a telephone, connected to the bridge tap.

Moreover, the present invention can provide a noise filter installed in a communications system which employs a two-wire transmission line for communications.

What is claimed is:

1. An impedance matching circuit with four ports having a two-wire transmission line for communications, comprising:
resistors connected in series with the two-wire transmission line; and
a capacitor connected in parallel with the two-wire transmission line.

2. A noise filter comprising:
an impedance matching circuit defined in claim 1; and
a filter circuit connected to the impedance matching circuit and comprising inductors and capacitors.

3. A noise filter according to claim 2, wherein the capacitor in the impedance matching circuit is eliminated when its action is conducted by the filter circuit.

4. A noise filter according to claim 2, wherein when a telephone is linked to a bridge tap branching from the main line of a communication device designed for performing communications over the two-wire transmission line, the noise filter is connected to the upstream end of the telephone.

5. A noise filter according to claim 3, wherein when a telephone is linked to a bridge tap branching from the main line of a communication device designed for performing communications over the two-wire transmission line, the noise filter is connected to the upstream end of the telephone.
